(19) United States
(12) Patent Application Publication
(10) Pub. No.: US 2026/0018431 A1
(43) Pub. Date: Jan. 15, 2026

(54) WAFER CLEANING APPARATUS

(71) Applicant: SAMSUNG ELECTRONICS CO., LTD., Suwon-si (KR)

(72) Inventors: KYOUNGWHAN OH, Suwon-si (KR); SUNGHUN JANG, Suwon-si (KR); HYUNWOONG HWANG, Suwon-si (KR)

(73) Assignee: SAMSUNG ELECTRONICS CO., LTD., Suwon-si (KR)

(21) Appl. No.: 18/982,580

(22) Filed: Dec. 16, 2024

(30) Foreign Application Priority Data
Jul. 9, 2024 (KR) 10-2024-0090678

(51) Int. Cl. H01L 21/67; H01L 21/683; H01L 21/687

(52) U.S. Cl. CPC H01L 21/67051; H01L 21/6838; H01L 21/68735

(57) ABSTRACT

A wafer cleaning apparatus may include: a center chuck configured to adhere a center of one surface of a wafer and rotate around a center axis of the center chuck, that extends in a first direction, to rotate the wafer; a side chuck including at least one grip part configured to support an edge of the one surface of the wafer; a housing including a guide part configured to guide the side chuck to move horizontally in a second direction perpendicular to the first direction; and at least one nozzle part configured to spray a cleaning solution toward the one surface of the wafer.

### CROSS-REFERENCE TO RELATED APPLICATION

This application claims priority to and the benefit of Korean Patent Application No. 10-2024-0090678, filed at the Korean Intellectual Property Office on Jul. 9, 2024, the entire contents of which are incorporated herein by reference.

### BACKGROUND

### 1 Field

Embodiments of the present disclosure relate to a wafer cleaning apparatus.

### 2. Description of Related Art

A photo process in the semiconductor manufacturing process is a process of coating a wafer with a photoresist (PR) that reacts to light from an exposure machine, and then exposing the applied photoresist to light that passes through a mask with a circuit pattern to take a precise photo, which includes an exposure process.

A spinner is equipment that coats the wafer with a photoresist immediately before exposure, and is used to evenly apply the photoresist to the wafer surface. When a wafer is mounted on a high-speed rotating spinner and a certain amount of the photoresist is supplied to the surface of the wafer through a nozzle, the photoresist is spread as the spinner rotates, and the wafer surface is coated with the photoresist. Approximately 30% of the supplied photoresist is coated on the wafer surface, but the remaining 70% is removed by flowing down from the wafer surface.

The photoresist that is not coated on the wafer surface reacts with various substances, some of which are present on the wafer in the form of particulates.

Accordingly, if the back surface of the wafer is not properly cleaned after applying the photoresist, particles flowing into the back surface of the wafer may become a problem.

In the exposure process, the back surface of the wafer is chucked to take a photo of the surface of the wafer coated with photoresist, as any particles between the chucking equipment and the back surface of the wafer may bend the wafer and cause defocusing. Defocusing refers to a phenomenon in which a photo is distorted due to the bending of the wafer.

In the exposure equipment, some correction for wafer bending may be made, but there are cases where correction is not possible depending on the size of the particle. Accordingly, the process of cleaning the back surface of the wafer before the exposure process is an important process for ensuring the quality of the exposure process.

### SUMMARY

Embodiments of the present disclosure solve the above issues, and provide a wafer cleaning apparatus capable of increasing the cleaning power of the wafer while increasing the replacement cycle of the equipment by cleaning one surface of the wafer using a non-contact twin-fluid nozzle method.

Further, embodiments of the present disclosure provide a wafer cleaning apparatus that reduces the possibility of mutual contamination during the cleaning process of each area by dualizing the cleaning process for the center and edge of one surface of the wafer.

In addition, embodiments of the present disclosure provide a wafer cleaning apparatus capable of preventing the cleaning solution sprayed during the cleaning process of one surface of the wafer from moving to another surface of the wafer and causing reverse contamination of the wafer.

According to embodiments of the present disclosure, a wafer cleaning apparatus may be provided and include: a center chuck configured to adhere a center of one surface of a wafer and rotate around a center axis of the center chuck, that extends in a first direction, to rotate the wafer; a side chuck including at least one grip part configured to support an edge of the one surface of the wafer; a housing including a guide part configured to guide the side chuck to move horizontally in a second direction perpendicular to the first direction; and at least one nozzle part configured to spray a cleaning solution toward the one surface of the wafer.

According to embodiments of the present disclosure, a wafer cleaning apparatus may be provided and include: a center chuck including a vacuum hole configured to adhere a center of one surface of a wafer, and rotate around a center axis of the center chuck, that extends in a first direction, to rotate the wafer; a side chuck including an arm part that has a ring shape, and a grip part inside the arm part and configured to contact an edge of the one surface of the wafer; a housing in which the center chuck and the side chuck are disposed, the housing including a guide part configured to guide the side chuck to move horizontally in a second direction perpendicular to the first direction; at least one nozzle part inside the housing and configured to spray a cleaning solution toward the one surface of the wafer; and a duct part inside the housing and configured to suck a portion of the cleaning solution scattered in the housing, wherein the center chuck includes a gas ejection part that is around the vacuum hole and configured to eject gas toward the one surface of the wafer.

According to embodiments of the present disclosure, a wafer cleaning apparatus may be provided and include: a center chuck configured to adhere a center of one surface of a wafer and rotate around a center axis of the center chuck; a side chuck configured to support an edge of the one surface of the wafer and horizontally move while supporting the wafer; a housing in which the center chuck and the side chuck are disposed, the housing including a guide part configured to guide horizontal movement of the side chuck; and a plurality of nozzle parts configured to spray a cleaning solution toward the one surface of the wafer, wherein the plurality of nozzle parts include: a first nozzle part configured to be below an area where a center of the wafer moves and clean the center of the wafer in a case where the side chuck is horizontally moved, and a second nozzle part configured to be below an area of the edge of the wafer and clean the edge of the wafer in a case where the center chuck rotates.

According to embodiment of the present disclosure, an increase in wafer cleaning efficiency may be provided by dualizing the cleaning of the center and edge areas of the wafer and using a non-contact twin-fluid cleaning method rather than a contact brush.

### BRIEF DESCRIPTION OF DRAWINGS

FIG. 1 illustrates a wafer cleaning apparatus according to an embodiment.

FIG. 2 illustrates the wafer cleaning apparatus according to the embodiment shown in FIG. 1.

FIG. 3 illustrates a center chuck in a wafer cleaning apparatus according to an embodiment.

FIG. 4 illustrates a side chuck in a wafer cleaning apparatus according to an embodiment.

FIGS. 5 to 8B illustrate various embodiments of a nozzle part in a wafer cleaning apparatus according to an embodiment.

FIGS. 9A-B illustrate a process of cleaning a center of a wafer using a wafer cleaning apparatus according to an embodiment.

FIGS. 10A-B illustrate a process of cleaning an edge of a wafer using a wafer cleaning apparatus according to an embodiment.

FIG. 11 illustrates a wafer cleaning apparatus according to an embodiment.

FIG. 12 illustrates a duct part in the wafer cleaning apparatus according to the embodiment shown in FIG. 11.

FIG. 13 illustrates an auxiliary cleaning part in the wafer cleaning apparatus according to embodiment shown in FIG. 11.

### DETAILED DESCRIPTION

Hereinafter, non-limiting example embodiments of the present disclosure will be described in detail with reference to the accompanying drawings, in which example embodiments of the present disclosure are shown. As those skilled in the art would realize, the described example embodiments may be modified in various different ways, all without departing from the spirit or scope of the present disclosure.

The drawings and description are to be regarded as illustrative in nature and not restrictive, and like reference numerals designate like elements throughout the specification.

In addition, size and thickness of each constituent element in the drawings may be arbitrarily illustrated for better understanding and ease of description, and the following example embodiments are not limited thereto. In the drawings, the thickness of layers, films, panels, regions, etc., may be exaggerated for clarity. In the drawings, the thickness of some layers and regions may be exaggerated for ease of description.

Throughout this specification and the claims that follow, when it is stated that an element is “coupled” to another element, it includes not only the case of being “directly coupled” but also “indirectly coupled” with another element therebetween. In addition, unless explicitly described to the contrary, the word “comprise” (or “include”) and variations such as “comprises” (or “includes”) or “comprising” (or “including”) should be understood to imply the inclusion of stated elements but not the exclusion of any other elements.

It should be understood that when an element such as a layer, film, region, or substrate is referred to as being “on” or “above” another element, it can be “directly on” the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” it in a direction opposite to gravity.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

In a semiconductor manufacturing process, an exposure process is an important process in which the horizontality of the wafer is important. In equipment that chucks the back surface of the wafer in the exposure process, the presence of particles on protruding supports (e.g., burrs) that abut the back surface of the wafer can cause bending of the wafer, resulting in defocusing.

Correction for wafer bending may be made during the exposure process. However, during argon fluoride immersion (ArF-I) or extreme ultraviolet (EUV) exposure in scanner equipment, particles of 2 to 5 μm in size are not corrected. Accordingly, there is an issue that defocusing of 25 nm occurs during exposure.

In order to minimize the defocusing phenomenon, it is beneficial to clean the back surface of the wafer before the exposure process. Particularly, it is beneficial to clean the back surface of the wafer of particles with a size of 2 to 5 μm that do not self-correct.

Comparative embodiments of wafer back surface cleaning technology generally use a contact cleaning method using a brush.

However, the method of the comparative embodiments require regular replacement of brushes, which are consumables, and there are many other related components for operating the cleaning equipment, which are not efficient in terms of cost and management. In addition, there is an issue of scratches occurring on wafers and chucking equipment due to friction between brushes and particles.

In addition, in the case of placing the wafer upside down so that the back surface of the wafer faces upward in comparative embodiments, the height of the equipment itself increases and the volume inevitably increases. Additionally, during the process of cleaning the back surface of the wafer in comparative embodiments, there is an issue that areas other than the back surface of the wafer are reversely contaminated by the sprayed cleaning solution.

A wafer cleaning apparatus 10 according to an embodiment of the present disclosure may provide a solution to the above issues.

Specifically, the wafer cleaning apparatus 10 may use a non-contact cleaning method using a twin-fluid cleaning nozzle, thereby minimizing equipment replacement and increasing efficiency in terms of cost and management. In addition, the volume of the equipment itself may be miniaturized by not placing the wafer upside down. In addition, by having a structure that prevents the cleaning solution from moving to areas other than the back surface of the wafer to be cleaned, reverse contamination of the wafer may be prevented.

Hereinafter, the wafer cleaning apparatus 10 according to an embodiment of the present disclosure will be described in more detail with reference to the drawings.

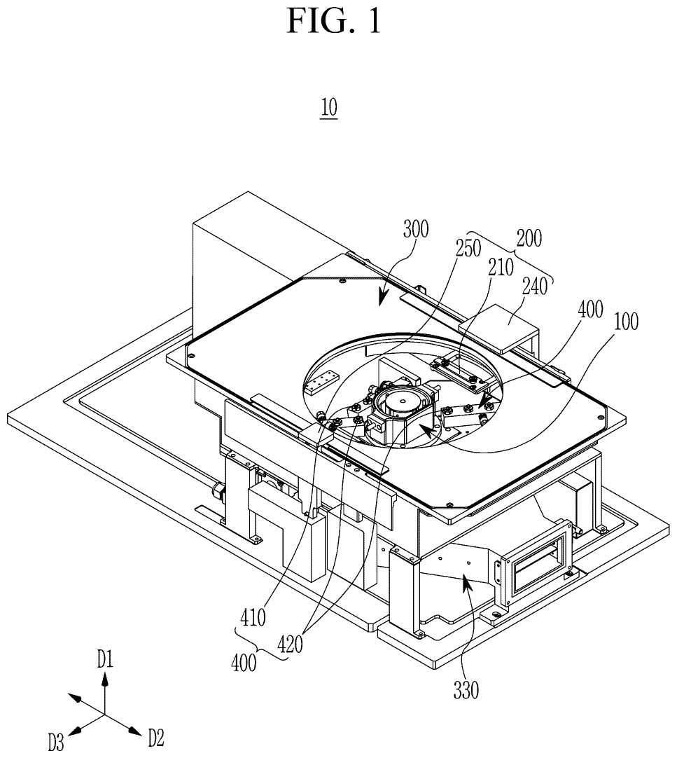

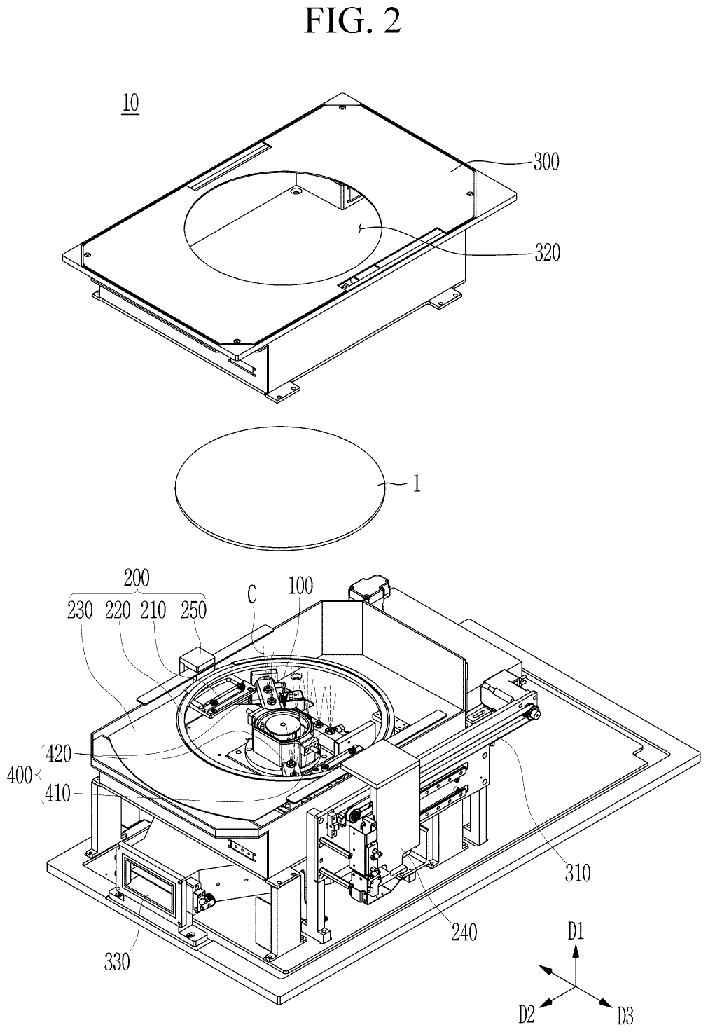

FIG. 1 illustrates a wafer cleaning apparatus according to an embodiment, and FIG. 2 illustrates the wafer cleaning apparatus according to the embodiment shown in FIG. 1.

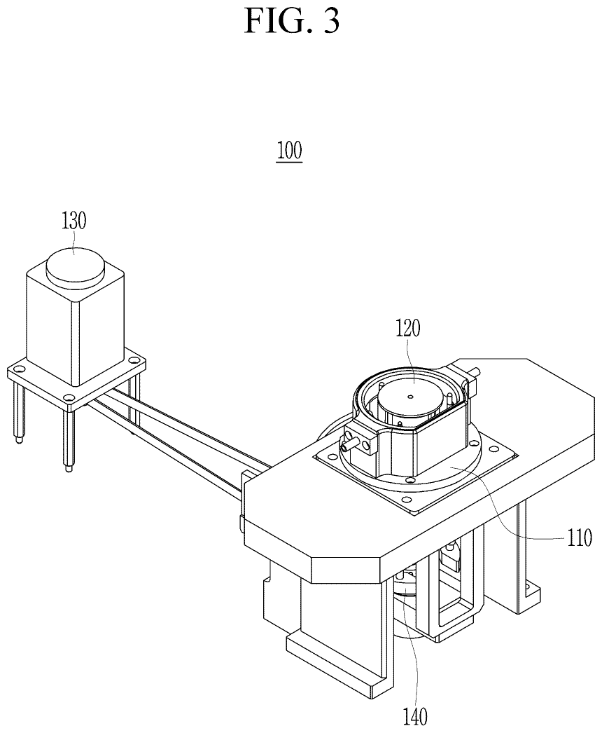

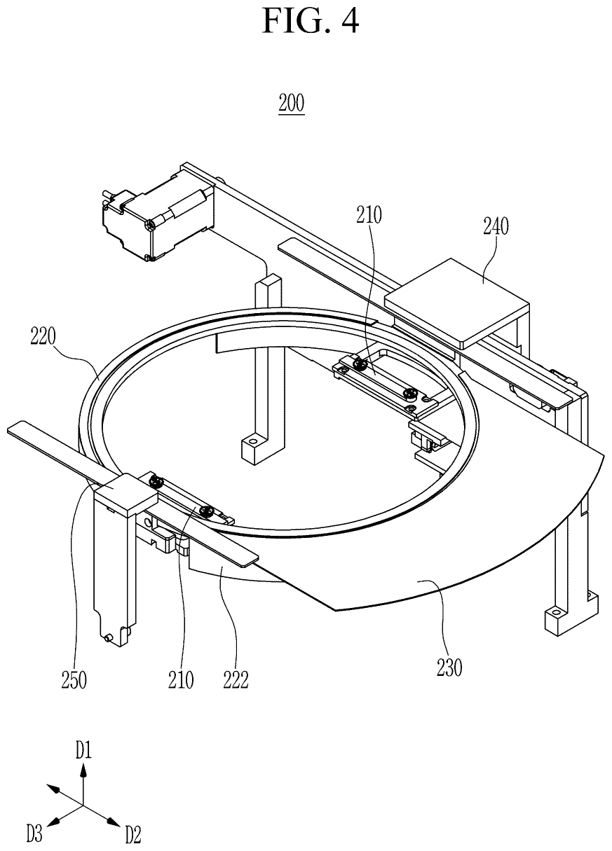

FIG. 3 illustrates a center chuck in a wafer cleaning apparatus according to an embodiment, and FIG. 4 illustrates a side chuck in a wafer cleaning apparatus according to an embodiment.

As shown in FIGS. 1 and 2, the wafer cleaning apparatus 10 according to the present disclosure may include a center chuck 100 supporting the center of one surface of a wafer 1, a side chuck 200 including a grip part 210 supporting an edge of the one surface of the wafer 1, a housing 300 coupled to the side chuck 200 through a coupling part 240 of the side chuck 200, and a nozzle part 400 spraying a cleaning solution C toward the one surface of the wafer 1.

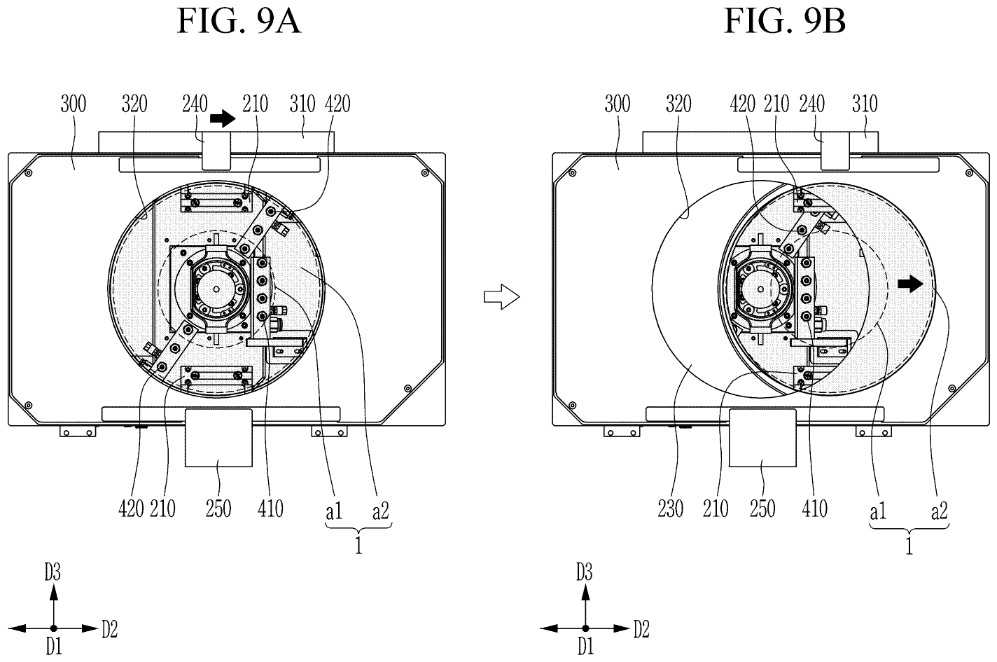

The center of the wafer 1 refers to an area including the center point of the wafer 1. The edge of the wafer 1 refers to an area surrounding the center of the wafer 1, excluding the center. The center area and edge area of the wafer 1 are shown in FIGS. 9A-B, and will be described below.

As shown in FIG. 2, the wafer 1 may be disposed to be seated on the grip part 210 provided in an arm part 220.

The diameter of the wafer 1 may be smaller than the inner diameter of the arm part 220 having a ring shape, and the wafer 1 may have a size that can be inserted into the ring structure of the arm part 220. At this time, the one surface of the wafer 1 may be disposed to face the grip part 210.

The center chuck 100, which is disposed below the wafer 1 and faces the one surface of the wafer 1, may adhere and fix the center area of the one surface of the wafer 1. The grip part 210 of the side chuck 200 may support the edge area of the one surface of the wafer 1.

The nozzle part 400 may spray the cleaning solution C toward the center and edge areas of the one surface of the wafer 1.

Referring to FIGS. 1 and 2, a first nozzle part 410 may clean the center of the one surface of the wafer 1, and two second nozzle parts 420 may clean the edge of the one surface of the wafer 1.

Although a total of three nozzle parts 400 are shown in the drawing, the number, shape, and arrangement position of the nozzle parts 400 are not limited to those shown. Depending on the purpose, the number, shape, and arrangement position of the nozzle parts 400 may be adjusted.

The wafer cleaning apparatus 10 according to an embodiment of the present disclosure may be characterized in that each nozzle part 400 cleans the center and the edge of the wafer 1 in a dualized manner.

First, the center chuck 100 may adhere the center of the one surface of the wafer 1 and rotate based on a first direction D1, which is an axial direction of the center, to rotate the wafer 1.

The second nozzle part 420 may spray the cleaning solution C toward the one surface of the wafer 1 rotating based on the axis of the center chuck 100. In this process, the edge area of the wafer 1 may be cleaned.

The side chuck 200 may include the grip part 210 supporting the edge of one surface of the wafer 1. Although only one grip part 210 is shown in FIG. 2, a plurality of the grip parts 210 may present as a pair facing each other. That is, the grip parts 210 may be disposed in a plural number.

The side chuck 200 may have a structure capable of horizontally moving along a second direction D2. The side chuck 200 may include a coupling part 240 that is connected to the housing 300 and moves horizontally in the second direction D2 perpendicular to the first direction D1.

The coupling part 240 may be coupled to a guide part 310 of the housing 300 and may guide the side chuck 200 to move horizontally in the second direction D2. That is, the coupling part 240 may horizontally move the side chuck 200 along the guide part 310 disposed along the second direction D2 perpendicular to the first direction D1.

While the side chuck 200 moves horizontally along the second direction D2 with the edge of the wafer 1 supported by the grip part 210, the first nozzle part 410 may spray the cleaning solution C toward the center of the one surface of the wafer 1. The first nozzle part 410 may be disposed in an area where the center of the wafer 1 moves horizontally.

As the side chuck 200 moves horizontally, the wafer 1 may also move and, in this process, the center area of the wafer 1 may pass above the first nozzle part 410. Accordingly, the first nozzle part 410 may clean the center area of the wafer 1.

The side chuck 200 may further include a plate 230 in the form of a plate extending along the second direction D2 to the outside of the arm part 220. The plate 230 will be described in detail with reference to FIGS. 4 and 9A-B.

The housing 300 may include a guide part 310 guiding the side chuck 200 to move horizontally in the second direction D2. The coupling part 240 of the side chuck 200 may have a structure movable along the guide part 310 while being coupled to the guide part 310.

The housing 300 may further include a through hole 320 on the upper side having a diameter equal to or greater than the diameter of the wafer 1. The upper side of the housing 300 may have a closed structure except for the through hole 320. The housing 300 may be a structure configured to prevent the cleaning solution C sprayed from the nozzle part 400 from flowing out of the upper side of the housing 300.

As shown in FIG. 2, the center chuck 100 and the side chuck 200 may be disposed inside the housing 300.

The wafer cleaning apparatus 10 according to an embodiment of the present disclosure may further include a duct part 330 for sucking the sprayed cleaning solution C in order to prevent the cleaning solution C from flowing into or out of the area to be cleaned.

The duct part 330 may be disposed close to the nozzle part 400 and may suction the cleaning solution C sprayed from the nozzle part 400.

The duct part 330 may absorb portions of the cleaning solution C scattered after cleaning the one surface of the wafer 1, and portions of the cleaning solution C moving in a path away from the one surface of the wafer 1.

The wafer cleaning apparatus 10 according to an embodiment of the present disclosure may clean the back surface of the wafer 1 before the exposure process, and may be applied to spinner equipment for applying photoresist.

However, the application is not limited to the above equipment, and may be applied to various equipment that cleans the wafer 1 using the cleaning solution C in addition to the spinner equipment.

In addition, embodiments of the present disclosure are not limited to cleaning the back surface of the wafer 1, and may be expanded and applied to various equipment for cleaning any one surface of the wafer 1.

Referring to FIGS. 1 to 3, the center chuck 100 may include a body 110 having one side (e.g., an upper side) supporting the wafer 1, a vacuum hole 120 disposed to penetrate from one side of the body 110 to adhere the wafer 1, a vacuum pump 130 providing suction force to the vacuum hole 120, and a rotation driver 140 (e.g., a motor) rotating the body 110.

The vacuum hole 120 disposed on the one side of the body 110 may be in contact with the center of the one surface of the wafer 1, and may adhere the center of the one surface of the wafer 1.

The wafer 1 fixed to the one side of the body 110 may be rotated based on the central axis (D1 direction) of the vacuum hole 120, that is, the central axis (D1 direction) of the wafer 1, according to the rotation of the body 110.

Referring to FIGS. 1, 2, and 4, the side chuck 200 may include the arm part 220 having a ring shape with an inner diameter equal to or greater than the diameter of the wafer 1, the grip part 210 disposed inside the arm part 220 having a ring shape and in contact with the one surface of the wafer 1, and the coupling part 240 connected to the arm part 220 and coupled to the guide part 310 of the housing 300.

The diameter of the wafer 1 may be smaller than the inner diameter of the arm part 220 having a ring shape, and the wafer 1 may have a size that may be inserted into the ring structure of the arm part 220.

When the diameter of the wafer 1 is significantly smaller than the inner diameter of the arm part 220, a large gap is created between the circumference of the wafer 1 and the inner circumference of the arm part 220. In this case, the cleaning solution C sprayed from the nozzle part 400 may flow out toward the other surface (e.g., the upper surface) of the wafer 1 through the above-mentioned gap.

Therefore, it is desirable that the inner diameter of the arm part 220 is larger than the diameter of the wafer 1, but that the difference is not large, and that the above-mentioned gap is as small as possible.

The grip parts 210 may be disposed in a plural number to be spaced apart from each other inside the arm part 220 having a ring shape. According to an embodiment, as shown in FIG. 4, the grip parts 210 may present as a pair facing each other. The grip part 210 may contact the edge area of the one surface of the wafer 1 and support the wafer 1.

As described with reference to FIG. 2, the coupling part 240 may be coupled to the guide part 310 of the housing 300 and horizontally move the side chuck 200 in the second direction D2.

As shown in FIG. 4, the side chuck 200 may include the plate 230 in the form of a plate extending along the second direction D2 to the outside of the arm part 220.

The plate 230 may minimize the gap that is created between the outer circumference of the arm part 220 and the through hole 320 of the housing when the side chuck 200 moves horizontally in the second direction D2 (refer to FIG. 9B).

Referring to FIG. 9B, which will be described below, when the side chuck 200 moves along the second direction D2, if there is no plate 230, a gap is created between the outer circumference of the arm part 220 having a ring shape and the through hole 320 of the housing.

According to embodiments of the present disclosure, the plate 230 may be disposed as shown in FIG. 9B, but if the plate 230 is not disposed in a comparative embodiment, the area where the plate 230 is currently disposed may be an empty area. In this case, the cleaning solution C sprayed from the nozzle part 400 toward the one surface of the wafer 1 through the space opened vertically from the through hole 320 may move to the other surface of the wafer 1, which may cause a problem.

The plate 230 may be configured to minimize reverse contamination of the other surface of the wafer 1 by the sprayed cleaning solution C flowing out onto the other surface of the wafer 1.

Additionally, as shown in FIG. 4, the side chuck 200 may further include a cover part 222 disposed along the circumference of the arm part 220 below the arm part 220. The cover part 222, which may have a height along the circumference of the arm part 220, may prevent the cleaning solution C sprayed along with the plate 230 from moving upward.

The side chuck 200 may further include a connection part 250 disposed on the opposite side to face the coupling part 240.

The connection part 250 may connect the side chuck 200 to the housing and, depending on the embodiment, may serve the same function as the coupling part 240.

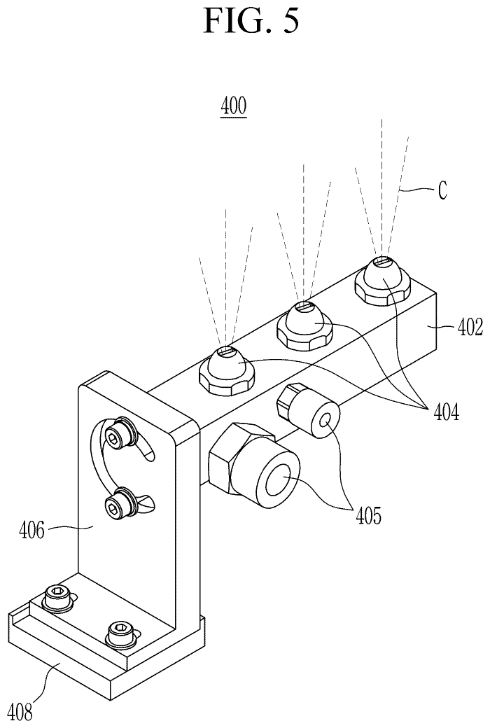

FIGS. 5 to 8 illustrate various embodiments of a nozzle part in a wafer cleaning apparatus according to an embodiment.

First, the nozzle part 400 (e.g., the first nozzle part 410 and/or the second nozzle part 420) according to an embodiment of the present disclosure may be disposed below the wafer 1 and spray the cleaning solution C toward the one surface of the wafer 1.

The nozzle part 400 may include a horizontal part 402 disposed to extend parallel to one surface of the wafer 1, a vertical part 406 vertically connected to one side of the horizontal part 402 and supporting the horizontal part 402, and a support part 408 coupled to the vertical part 406 and supporting and connecting the vertical part 406 to the housing 300.

The nozzle part 400 may include a cleaning solution spraying part 404 (e.g., at least one outlet such as at least one nozzle) disposed on the horizontal part 402 and spraying the cleaning solution C toward the one surface of the wafer 1. Additionally, the nozzle part 400 may further include a cleaning solution injection part 405 (e.g., at least one inlet) injecting the cleaning solution C into the nozzle part 400.

The nozzle part 400 according to an embodiment of the present disclosure may implement a twin-fluid nozzle method that sprays a mixture of a gas and a liquid.

The twin-fluid nozzle method is a method that cleans the wafer 1 by causing mist formed when spraying a mixture of gas and liquid to collide with the surface of the wafer 1. It is possible to achieve a higher cleaning effect compared to a brush or laser beam by using a small amount of mist.

The twin-fluid nozzle type may be divided into an internal mixing type and an external mixing type.

In the case of the internal mixing method, the liquid and gas are mixed inside the nozzle and then finely sprayed, so the flows of the liquid and gas are non-independent. Accordingly, changes in gas flow may affect liquid flow. The internal mixing method allows the creation of various spray patterns and has the advantage of a strong cleaning power.

In the case of the external mixing method, the liquid and gas are mixed outside the nozzle and finely sprayed at the same time. As liquid and gas are injected through each nozzle, the flows of liquid and gas may be controlled independently. Therefore, the external mixing method may be effectively used for spraying high-viscosity liquids and polishing liquids. The external mixing method has the advantage of being able to form small and uniform mist and of being able to independently control supply conditions.

There may be two cleaning solution injection parts 405 of the nozzle part 400, and liquid and gas may be injected into each. For example, liquid and gas may both be injected into each of the two cleaning solution injection parts 405. Alternatively, liquid may be injected into one of the two cleaning solution injection parts 405, and gas may be injected into the other of the two cleaning solution injection parts 405.

Here, the liquid may include NH₄OH, N₂O₂, DI water (DIW), hot DIW, thinner, acid thinner, standard clean-1 (SC-1), or the like.

The gas may include compressed dry air (CDA) or nitrogen gas (N₂).

The cleaning solution spraying part 404 of the nozzle part 400 may spray the mixture of liquid and gas in the form of a spray. During this process, micro bubbles may be generated.

The nozzle part 400 may be disposed close to the center chuck 100 so that the horizontal part 402 faces the one surface (center or edge) of the wafer 1 (see FIGS. 2 and 5).

According to the embodiment, the nozzle part 400 (e.g., the first nozzle part 410 and/or the second nozzle part 420) may be disposed so that the one surface of the horizontal part 402 faces the upper side, as shown in FIG. 5.

When the horizontal part 402 is disposed as shown in FIG. 5, the cleaning solution spraying part 404 disposed on the horizontal part 402 is disposed to face the upper side. At this time, the cleaning solution spraying part 404 may spray the cleaning solution C toward the one surface of the wafer 1, perpendicular to the one surface of the wafer 1.

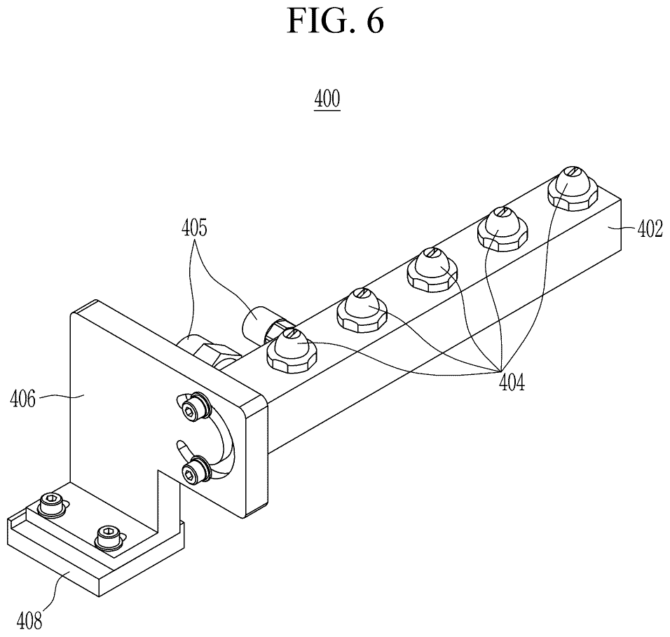

FIG. 6 shows another form of the nozzle part 400 (e.g., the first nozzle part 410 and/or the second nozzle part 420).

As shown in FIG. 6, there may be five cleaning solution spraying parts 404 disposed on the horizontal part 402. The number of cleaning solution spraying parts 404 is not limited to the amount shown, and the number may be four or less or six or more.

Additionally, the shape of the vertical part 406 is not limited to the shape shown in FIGS. 5 and 6. The vertical part 406 is vertically connected to one side of the horizontal part 402 and serves to support the horizontal part 402.

Accordingly, the vertical part 406 may have any shape as long as it is disposed between the horizontal part 402 and the support part 408 and vertically connects the horizontal part 402 and the support part 408.

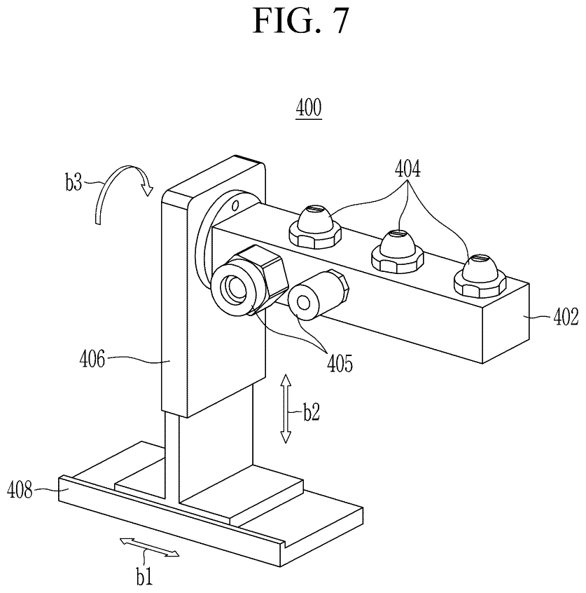

FIG. 7 shows the nozzle part 400 (e.g., the first nozzle part 410 and/or the second nozzle part 420) according to another embodiment.

Unlike in FIGS. 5 and 6, the vertical part 406 shown in FIG. 7 has a structure that is adjustable in position and in length.

First, the vertical part 406 is capable of horizontal movement along the length direction (e.g., horizontal direction b1) of the horizontal part 402. That is, the vertical part 406 may be coupled to the support part 408 so that the vertical part 406 is slidable in the horizontal direction (e.g., the horizontal direction b1) on the support part 408 while coupled to the support part 408.

Additionally, the length of the vertical part 406 is adjustable along the vertical direction b2 of the vertical part 406. That is, the vertical part 406 may have a height-adjustable structure.

By adjusting the position and length of the vertical part 406 along the horizontal direction b1 and the vertical direction b2 shown in FIG. 7, the position and height of the cleaning solution spraying parts 404 may be adjusted.

The plurality of nozzle parts 400 are adjustable in the horizontal direction b1 and the vertical direction b2 of FIG. 7, and may be adjusted individually or simultaneously.

Additionally, the plurality of nozzle parts 400 may be set to automatically vary and adjust during the process.

The wafer cleaning apparatus 10 according to an embodiments of the present disclosure may improve the cleaning efficiency of the wafer 1 by adjusting the position of the cleaning solution spraying part 404 that sprays the cleaning solution C when the wafer 1 is moved horizontally (in the direction D2) or rotated based on the center axis (in the direction D1) during the cleaning process of the wafer 1.

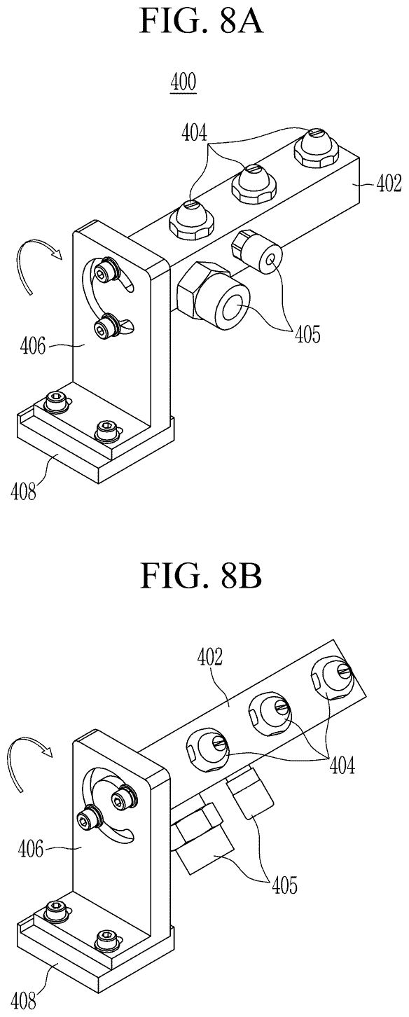

The direction b3 shown in FIG. 7 indicates the direction in which the horizontal part 402 rotates around an axis extending in the length direction of the horizontal part 402. The horizontal part 402 may rotate at a certain angle along the direction b3. This will be described with reference to FIG. 8.

FIGS. 8A-B are diagrams for describing the rotation of the horizontal part 402 in the direction b3 of FIG. 7.

FIG. 8A shows the horizontal part 402 before rotation, and FIG. 8B shows the horizontal part 402 rotated in the direction shown in FIG. 8A. The horizontal part 402 in FIG. 8B is rotated clockwise by approximately 45 degrees.

In the state of FIG. 8A, the cleaning solution C sprayed from the cleaning solution spraying part 404 is directed vertically upward, and accordingly, most of the cleaning solution C hits the one surface of the wafer 1 vertically.

In contrast, in the state shown in FIG. 8B, the cleaning solution C sprayed from the cleaning solution spraying part 404 is sprayed diagonally upward. That is, when the cleaning solution C hits the one surface of the wafer 1, the angle formed between most of the cleaning solution C and the wafer 1 is an acute angle.

As shown in FIGS. 8A-B, by adjusting the rotation angle of the horizontal part 402, the spraying speed (hitting force), the spraying direction, and the spray area of the cleaning solution C hitting the one surface of the wafer 1 may adjusted.

According to embodiments, the wafer cleaning apparatus 10 may include a controller configured to adjust the angle. The angle may be adjusted by the user, or may be set to automatically vary and adjust during the process. The controller may include, for example, at least one processor and memory storing computer instructions. The computer instructions may be configured to, when executed by the at least one processor, cause the controller to perform its functions.

According to embodiments, the controller may be alternatively or additionally configured to adjust the position and length of the vertical part 406 along the horizontal direction b1 and the vertical direction b2 shown in FIG. 7. For example, the controller may be configured to control at least one actuator of the wafer cleaning apparatus 10 (e.g., the nozzle parts 400) that is configured to cause the position and length of the vertical part 406 along the horizontal direction b1 and the vertical direction b2 to change, and/or adjust the rotation angle of the horizontal part 402 in the direction b3.

Each horizontal part 402 of the plurality of nozzle parts 400 may be rotated as shown in FIGS. 8A and 8B to adjust the angle at which the cleaning solution C is sprayed, and may be rotated individually or simultaneously (e.g., by a same or different actuator(s)).

When the wafer 1 is moved horizontally or rotated about the center axis during the process of cleaning the one surface of the wafer 1, the angle of rotation of the horizontal part 402 may be adjusted to spray the cleaning solution C at an optimal angle corresponding to the linear velocity of the wafer 1.

In the cleaning process using the nozzle part 400, differences in the cleaning force are generated by adjusting the cleaning conditions, including the mixing ratio of the cleaning solution C, the distance (including angle) between the cleaning solution spraying part 404 and the one surface of the wafer 1, and the pressure at which the cleaning solution C is sprayed.

Examples of the mixing ratio of the cleaning solution C include a case where a mixing target is a ratio of air and DIW, and a case where the mixing target is a ratio of nitrogen (N₂) and DIW. The mixing ratio may be adjusted between 40:1 and 200:1.

In the wafer cleaning apparatus 10 according to embodiments of the present disclosure, the cleaning power of the wafer 1 may be improved by adjusting the cleaning conditions, and cleaning efficiency may be maximized by simultaneously shortening the time required.

According to embodiments of the present disclosure, the nozzle parts 400 may include the first nozzle part 410 spraying the cleaning solution C toward the center (e.g., wafer center a1 shown in FIGS. 9A-B and 10A-B) of the wafer 1, and the second nozzle part 420 spraying the cleaning solution C toward the edge (e.g., the wafer edge a2 shown in FIGS. 9A-B and 10A-B) of the wafer 1 (see FIG. 2).

The first nozzle part 410 may have the horizontal part 402 to be disposed parallel to the third direction D3, which is perpendicular to the second direction D2.

The second nozzle part 420 may have the horizontal part 402 to be disposed from the edge of the wafer 1 toward the center of the wafer 1. The second nozzle part 420 may be disposed in a plural number.

The process of dually cleaning the center and edge areas of the wafer 1 using the first nozzle part 410 and the second nozzle part 420 will be described with reference to FIGS. 9A-B and 10A-B.

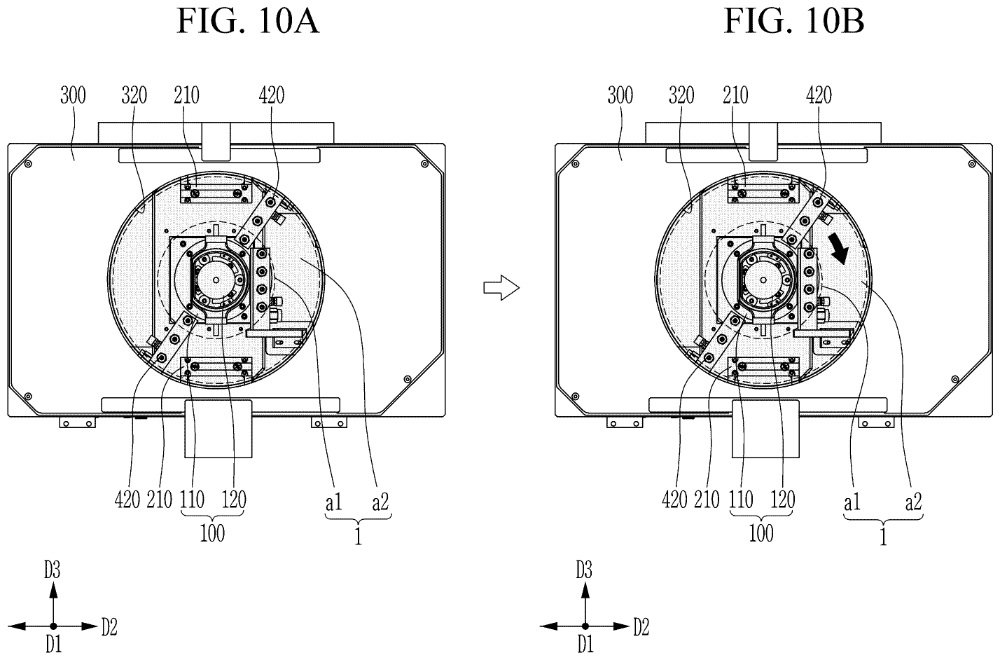

FIGS. 9A-B illustrate a process of cleaning the center of a wafer using a wafer cleaning apparatus according to an embodiment, and FIGS. 10A and 10B illustrate a process of cleaning the edge of a wafer using a wafer cleaning apparatus according to an embodiment.

The wafer cleaning apparatus 10 according to the embodiment of the present disclosure may include the center chuck 100 adhering the center of the one surface of the wafer 1 and rotating based around an axis of the center (in the direction D1), the side chuck 200 supporting the an edge of one surface of the wafer 1 and moving horizontally (in the direction D2) while supporting the wafer 1, the housing 300 in which the center chuck 100 and the side chuck 200 are disposed, and including the guide part 310 guiding the horizontal movement of the side chuck 200, and the plurality of nozzle parts 400 spraying the cleaning solution C toward the one surface of the wafer 1.

The nozzle part 400 may include the first nozzle part 410 and the second nozzle part 420.

The first nozzle part 410 may be disposed below the area where the center of the wafer 1 moves when the side chuck 200 moves horizontally, and clean the center of the wafer 1.

The second nozzle part 420 may be disposed below the edge area of the wafer 1 when the center chuck 100 rotates, and clean the edge of the wafer 1.

First, the process of cleaning the center of the wafer 1 is shown in FIGS. 9A-B.

The first nozzle part 410 has the horizontal part 402 to be disposed parallel to the third direction D3. The first nozzle part 410 is disposed to correspond to an area where the center of the wafer 1 moves when the wafer 1 is horizontally moved, so that the center of the wafer 1 may be cleaned.

FIGS. 9A and 9B correspond to the process of cleaning the center of the wafer 1, where the center of the wafer 1 is not adhered on the center chuck 100 and the edge of the wafer 1 is seated in the grip part 210.

FIG. 9A shows the initial state before cleaning the center of the wafer 1, and shows the center of the wafer 1 disposed at a position corresponding to the center chuck 100.

FIG. 9B shows a process of cleaning the center of the wafer 1, with the side chuck 200 moving horizontally in the second direction (direction D2), such that the center of the wafer 1 moves away from the center chuck 100.

Horizontal movement of the side chuck 200 in the second direction (direction D2) may be achieved while the coupling part 240 moves along the guide part 310 of the housing 300, as described in FIG. 2.

As shown in FIG. 9B, during the horizontal movement of the side chuck 200, the first nozzle part 410 disposed close to the center chuck 100 sprays the cleaning solution C toward the center of the one surface of the wafer 1.

That is, the cleaning solution C is sprayed from the horizontal part 402 (cleaning solution spraying part 404) of the first nozzle part 410 that extends in the direction (the third direction D3) perpendicular to the direction (the second direction D2) in which the wafer 1 moves.

At this time, by adjusting the height and position of the cleaning solution injection part 405 disposed on the horizontal part 402 of the first nozzle part 410 (see FIGS. 7 and 8), the cleaning efficiency centered on the wafer 1 is improved.

As described above, the cover part 222 and the plate 230 serve to block a part of the through hole 320 of the housing 300, thereby minimizing the flow of the cleaning solution C sprayed from the first nozzle part 410 through the through hole 320 to the outside of the housing 300.

Next, the process of cleaning the edge of the wafer 1 will be described referring to FIGS. 10A and 10B.

The second nozzle part 420 has the horizontal part 402 to be disposed from the edge of the wafer 1 toward the center of the wafer 1. The second nozzle part 420 disposed in an area corresponding to the edge of the wafer 1 may clean the edge of the wafer 1.

FIGS. 10A and 10B show the process of cleaning the edge of the wafer 1. In FIG. 10A, the wafer 1 is not fixed to the grip part 210, and the center of the wafer 1 is fixed by being adhered to the vacuum hole 120 of the center chuck 100.

FIG. 10B shows the edge of the wafer 1 being cleaned, and the wafer 1 adhered to the vacuum hole 120 is rotated around the center axis (D1 direction).

At this time, the second nozzle part 420 disposed at the edge area of the wafer 1 may spray the cleaning solution C to clean the edge of the wafer 1.

As shown in FIGS. 9A-B and 10A-B, by separately performing the cleaning process on the center and edge of the wafer 1, the possibility of mutual contamination during the cleaning process of each area may be minimized.

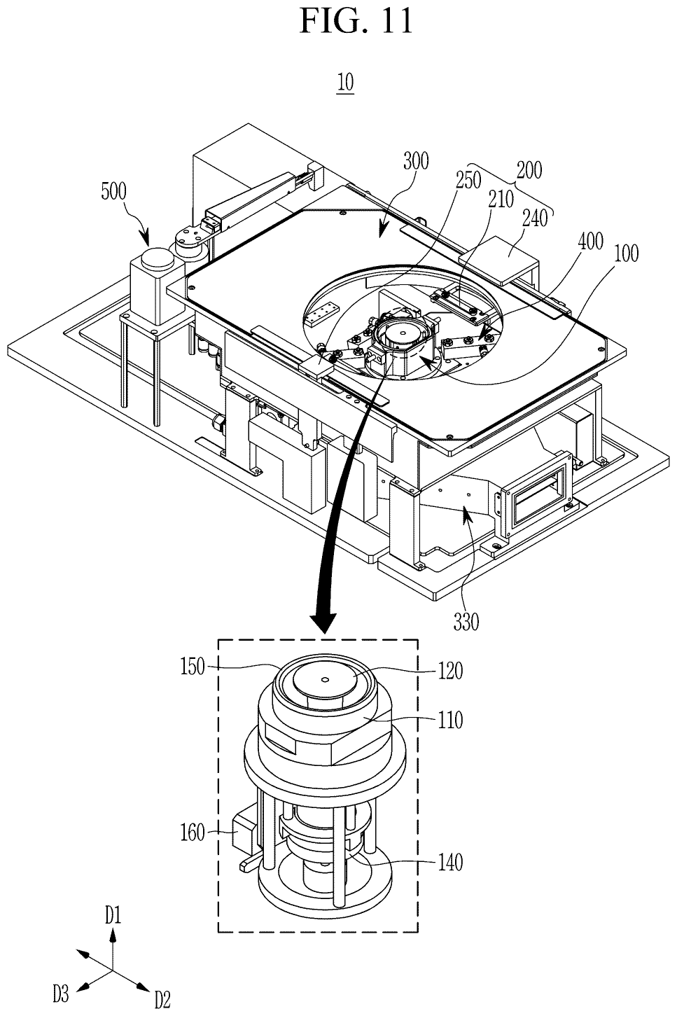

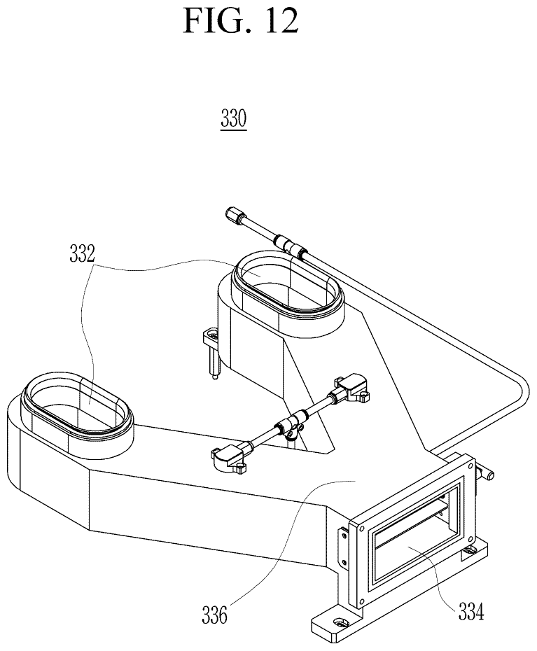

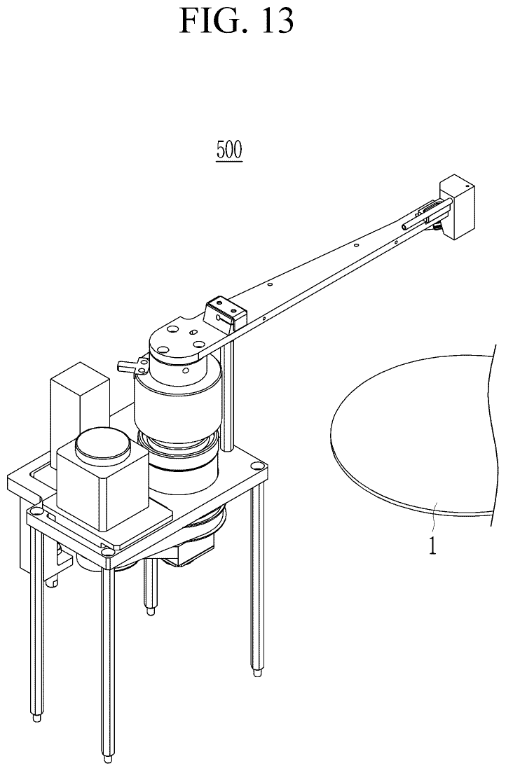

FIG. 11 illustrates a wafer cleaning apparatus according to an embodiment, FIG. 12 illustrates a duct part in the wafer cleaning apparatus according to FIG. 11, and FIG. 13 illustrates an auxiliary cleaning part in the wafer cleaning apparatus according to FIG. 11.

As shown in FIG. 11, the wafer cleaning apparatus 10 according to an embodiment may include, as in FIGS. 1 and 2, the center chuck 100, the side chuck 200, the housing 300, the nozzle part 400, and the duct part 330 disposed inside the housing 300 and sucking the cleaning solution C scattered in the housing 300.

The center chuck 100 may include the vacuum hole 120 adhering the center of the one surface of the wafer 1, and may rotate around an axis extending in the first direction D1, which is the center axis direction, to rotate the wafer 1.

The side chuck 200 may include the arm part 220 having a ring shape, and the grip part 210 disposed inside the arm part 220 (see FIG. 2), in contact with the edge of the one surface of the wafer 1, to support the wafer 1.

The center chuck 100 and the side chuck 200 may be disposed inside the housing 300. The housing 300 may include the guide part 310 (see FIG. 2) guiding the side chuck 200 to move horizontally along the second direction D2.

The nozzle part 400 may be disposed inside the housing 300 and may spray the cleaning solution C toward the one surface of the wafer 1.

Since the wafer cleaning apparatus 10 according to FIG. 11 may have a same or similar configuration as the wafer cleaning apparatus 10 according to the embodiment shown in FIGS. 1 and 2, repeated description of the same configuration may be omitted. Below, differences in configurations will be described.

Unlike in FIGS. 1 and 2, the center chuck 100 according to the embodiment of FIG. 11 may include a gas ejection part 150 disposed around the vacuum hole 120 and ejecting gas toward the one surface of the wafer 1.

The gas ejection part 150 serves to eject air vertically toward the one surface of the wafer 1. The gas ejected in this way may have an air curtain function.

According to a comparative embodiment, in the process of adhering the one surface of the wafer 1 in the vacuum hole 120, there may be an issue that some liquid, such as DIW, may flow in through the vacuum hole 120. Accordingly, by arranging an air curtain to surround the vacuum hole 120, foreign substances may be prevented from flowing into the vacuum hole 120.

According to the embodiment, the gas ejection part 150 may have a line shape surrounding the vacuum hole 120. Since the gas ejection part 150 has a line shape, it is possible to completely block liquid from flowing into the vacuum hole 120.

The center chuck 100 may further include a gas supplier 160 that supplies gas to the gas ejection part 150.

The wafer cleaning apparatus 10 according to FIG. 11 may further include an auxiliary cleaning part 500 for spraying the cleaning solution C on the other surface of the wafer 1 (see FIG. 12), and may further include the duct part 330.

The auxiliary cleaning part 500 may spray the cleaning solution C onto the other surface of the wafer 1 visible through the through hole 320 (see FIG. 2) of the housing 300. The position of the auxiliary cleaning part 500 is not limited to the position shown in FIG. 11. Any position where the cleaning solution C can be sprayed on the other surface of the wafer 1 is possible.

The cleaning solution C sprayed by the auxiliary cleaning part 500 may include DI water (DIW), thinner, acid thinner, or the like.

The duct part 330 may serve to suction the cleaning solution C sprayed from the nozzle part 400.

The duct part 330 may include a suction port 332 having two holes for sucking the cleaning solution C, at least one outlet 334 for discharging the sucked cleaning solution C to the outside, and a duct 336 connecting the suction port 332 and the at least one outlet 334. Depending on the embodiment, the duct 336 may have a “Y” shape.

The duct part 330 may prevent the sprayed cleaning solution C from flowing into or out of the area to be cleaned, such as the other surface of the wafer 1. The duct part 330 may be disposed close to the nozzle part 400.

While non-limiting example embodiments of the present disclosure have been described in connection with the drawings, it should be understood that the present disclosure is not limited to the example embodiments. On the contrary, various modifications and equivalent arrangements are included within the spirit and scope of the present disclosure.

What is claimed is:

1. A wafer cleaning apparatus, comprising:
a center chuck configured to adhere a center of one surface of a wafer and rotate around a center axis of the center chuck, that extends in a first direction, to rotate the wafer;
a side chuck comprising at least one grip part configured to support an edge of the one surface of the wafer;
a housing comprising a guide part configured to guide the side chuck to move horizontally in a second direction perpendicular to the first direction; and
at least one nozzle part configured to spray a cleaning solution toward the one surface of the wafer.

2. The wafer cleaning apparatus of claim 1, wherein the center chuck comprises:
a body comprising one side configured to support the one surface of the wafer;
a vacuum hole that penetrates the one side of the body to adhere the wafer;
a vacuum pump configured to provide a suction force to the vacuum hole; and
a rotation driver configured to rotate the body.

3. The wafer cleaning apparatus of claim 1, wherein the side chuck comprises:
an arm part comprising a ring shape having an inner diameter equal to or greater than a diameter of the wafer;
a plate extending along the second direction to an outside of the arm part; and
a coupling part connected to the arm part and coupled to the guide part,
wherein the at least one grip part is inside the arm part and configured to contact with the one surface of the wafer.

4. The wafer cleaning apparatus of claim 3, wherein the at least one grip part is a plurality of grip parts that are spaced apart from each other inside the arm part.

5. The wafer cleaning apparatus of claim 1, wherein the housing further comprises:
a through hole having a diameter equal to or greater than the diameter of the wafer, the through hole configured to be at an upper side of the wafer.

6. The wafer cleaning apparatus of claim 1, further comprising:
an auxiliary cleaning part configured to spray the cleaning solution on another surface of the wafer, opposite to the one surface of the wafer.

7. The wafer cleaning apparatus of claim 1, wherein each of the at least one nozzle part comprises:
a horizontal part that extends parallel to the one surface of the wafer;
a cleaning solution spraying part on the horizontal part and configured to spray the cleaning solution toward the one surface of the wafer;
a vertical part vertically connected to one side of the horizontal part and supporting the horizontal part; and
a support part coupled to the vertical part and connecting the vertical part and the housing.

8. The wafer cleaning apparatus of claim 7, wherein
the horizontal part is configured to face the one surface of the wafer.

9. The wafer cleaning apparatus of claim 7, wherein the at least one nozzle part comprises:
a first nozzle part configured to spray the cleaning solution toward a center of the wafer; and
at least one second nozzle part configured to spray the cleaning solution toward the edge of the wafer.

10. The wafer cleaning apparatus of claim 9, wherein
the horizontal part of the first nozzle part extends parallel to a third direction that is perpendicular to the first direction and the second direction.

11. The wafer cleaning apparatus of claim 9, wherein
the horizontal part of the at least one second nozzle part extends from the edge of the wafer towards the center of the wafer.

12. The wafer cleaning apparatus of claim 11, wherein
the at least one second nozzle part is a plurality of second nozzle parts.

13. A wafer cleaning apparatus, comprising:
a center chuck comprising a vacuum hole configured to adhere a center of one surface of a wafer, and rotate around a center axis of the center chuck, that extends in a first direction, to rotate the wafer;
a side chuck comprising an arm part that has a ring shape, and a grip part inside the arm part and configured to contact an edge of the one surface of the wafer;
a housing in which the center chuck and the side chuck are disposed, the housing comprising a guide part configured to guide the side chuck to move horizontally in a second direction perpendicular to the first direction;
at least one nozzle part inside the housing and configured to spray a cleaning solution toward the one surface of the wafer; and
a duct part inside the housing and configured to suck a portion of the cleaning solution scattered in the housing,
wherein the center chuck comprises a gas ejection part that is around the vacuum hole and configured to eject gas toward the one surface of the wafer.

14. The wafer cleaning apparatus of claim 13, further comprising:
a gas supplier configured to supply gas to the gas ejection part.

15. The wafer cleaning apparatus of claim 13, wherein the duct part comprises:
a suction port comprising two holes that are configured to suck the cleaning solution;
an outlet configured to discharge the cleaning solution, that is sucked by the suction port, to an outside; and
a duct connecting the suction port and the outlet,
wherein the duct has a “Y” shape.

16. The wafer cleaning apparatus of claim 13, wherein each of the at least one nozzle part comprises:
a horizontal part extending parallel to the one surface of the wafer;
a plurality of cleaning solution spraying parts on the horizontal part and configured to spray the cleaning solution toward the one surface of the wafer;
a vertical part vertically connected to one side of the horizontal part and supporting the horizontal part; and
a support part coupled to the vertical part and connecting the vertical part and the housing.

17. The wafer cleaning apparatus of claim 16, wherein
the vertical part is configured to be adjusted in length along a length direction of the vertical part.

18. The wafer cleaning apparatus of claim 16, wherein
the vertical part is configured to horizontally move along a length direction of the horizontal part.

19. The wafer cleaning apparatus of claim 16, wherein the horizontal part is configured to rotate around an axis that extends in a length direction of the horizontal part.

20. A wafer cleaning apparatus, comprising:
a center chuck configured to adhere a center of one surface of a wafer and rotate around a center axis of the center chuck;
a side chuck configured to support an edge of the one surface of the wafer and horizontally move while supporting the wafer;
a housing in which the center chuck and the side chuck are disposed, the housing comprising a guide part configured to guide horizontal movement of the side chuck; and
a plurality of nozzle parts configured to spray a cleaning solution toward the one surface of the wafer,
wherein the plurality of nozzle parts comprise:
a first nozzle part configured to be below an area where a center of the wafer moves and clean the center of the wafer in a case where the side chuck is horizontally moved, and
a second nozzle part configured to be below an area of the edge of the wafer and clean the edge of the wafer in a case where the center chuck rotates.
